(19) United States
(12) Patent Application Publication
(10) Pub. No.: US 2010/0166945 A1
(43) Pub. Date: Jul. 1, 2010

(54) Methods of calculating thicknesses of layers and methods of forming layers using the same

(75) Inventors: Ho-Ki Lee, Anyang-si (KR); Sung-Ho Han, Seoul (KR); Yong-Jin Kim, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/654,721

(22) Filed: Dec. 30, 2009

(30) Foreign Application Priority Data
Dec. 30, 2008 (KR) 10-2008-0136252

(51) Int. Cl. C23C 14/54; C23C 16/513

(52) U.S. Cl. 427/10

(57) ABSTRACT

A method of calculating a thickness of a layer may include forming the layer on a substrate in a chamber, measuring optical emission spectrum data from the chamber, and calculating the thickness of the layer from the optical emission spectrum data. A method of forming a layer may include depositing the layer on a substrate in a chamber, measuring optical emission spectrum data from the chamber, calculating a thickness of the layer using the optical emission spectrum data, and ending the depositing of the layer when the calculated thickness of the layer is within a target thickness range.

### CROSS-REFERENCE TO RELATED APPLICATION(S)

This application claims priority from Korean Patent Application No. 10-2008-0136252, filed on Dec. 30, 2008, in the Korean Intellectual Property Office (KIPO), the entire contents of which are incorporated herein by reference.

### BACKGROUND

1. Field

Example embodiments relate to methods of calculating thicknesses of layers and/or methods of forming layers using the same. Also, example embodiments relate to methods of calculating thicknesses of layers formed on substrates and/or methods of forming layers using the same.

2. Description of the Related Art

Generally, after forming a layer on a substrate, whether the layer has a desired thickness or not may be confirmed. The thickness of the layer may be measured by an additional process using a measurement apparatus. However, when a plurality of layers is formed on the substrate, measuring the thicknesses of the layers may be performed several times, which may increase the manufacture time and/or decrease the manufacture efficiency. Accordingly, a method of calculating the thicknesses of layers that does not require an additional process may be needed.

### SUMMARY

Example embodiments may provide methods of calculating thicknesses of layers formed on substrates in real time.

Example embodiments also may provide methods of forming layers having a desired thickness using the above measurement methods.

According to example embodiments, there may be provided a method of calculating a thickness of a layer. In the method, a layer may be formed on a substrate in a chamber. Optical emission spectrum data from the chamber may be measured. A thickness of the layer may be calculated from the optical emission spectrum data.

In example embodiments, when the thickness of the layer is calculated, a speed of formation of the layer may be calculated from the optical emission spectrum data using an equation between the optical emission spectrum data and the speed of formation of the layer. The equation may be integrated over time.

In example embodiments, the equation may include the optical emission spectrum data multiplied by a function of one or more of an internal pressure of the chamber, a temperature of the chamber, a flow rate of source gas, and a power applied to the chamber.

In example embodiments, when the function is obtained, a sample layer may be deposited on a substrate in the chamber. Optical emission spectrum data from the chamber may be detected during the deposition of the sample layer. The substrate having the sample layer may be unloaded from the chamber. A thickness of the sample layer may be measured. The function may be obtained using relationship between the optical emission spectrum data and the measured thickness of the layer.

In example embodiments, when the layer is formed on the substrate, a chemical vapor deposition (CVD) process using a source gas and a carrier gas may be performed.

In example embodiments, the carrier gas may include inert gas.

In example embodiments, the optical emission spectrum data may be an intensity of light from the chamber at a wavelength of the inert gas.

According to example embodiments, there may be provided a method of forming a layer. In the method, a layer may be deposited on a substrate in a chamber. Optical emission spectrum data emitted from the chamber may be measured. A thickness of the layer may be calculated using the optical emission spectrum data. The deposition of the layer may end when the calculated thickness of the layer is within a target range.

example embodiments, when the thickness of the layer is calculated, the optical emission spectrum data may be applied to an equation for calculating a speed of deposition of the layer and/or the equation may be integrated over time. The equation may include the optical emission spectrum data and/or deposition conditions.

According to example embodiments, a thickness of a layer may be calculated in real time during a deposition process and/or the layer may be formed to have a target thickness.

According to example embodiments, a method of calculating a thickness of a layer may include forming the layer on a substrate in a chamber, measuring optical emission spectrum data from the chamber, and/or calculating the thickness of the layer from the optical emission spectrum data.

According to example embodiments, a method of forming a layer may include depositing the layer on a substrate in a chamber, measuring optical emission spectrum data from the chamber, calculating a thickness of the layer using the optical emission spectrum data, and/or ending the depositing of the layer when the calculated thickness of the layer is within a target thickness range.

### BRIEF DESCRIPTION OF THE DRAWINGS

These and/or other aspects and advantages will become more apparent and more readily appreciated from the following detailed description of example embodiments, taken in conjunction with the accompanying drawings, in which:

FIG. 1 is an apparatus for depositing of a layer on a substrate according to example embodiments;

FIG. 2 is a flowchart illustrating a method of calculating a thickness of the layer according to example embodiments;

FIG. 3 is a flowchart illustrating a method of obtaining Equation (1) from optical emission spectrum data;

FIG. 4 is a flowchart illustrating a method of calculating thicknesses of layers formed on a substrate in real time;

FIG. 5 is a graph showing peak values of optical emission spectrum data of Sample 1 to 5 and thicknesses of Sample 1 to 5 measured by ellipsometry; and

FIG. 6 is a graph showing peak values of optical emission spectrum data of Sample 6 to 10 and thicknesses of Sample 6 to 10 measured by ellipsometry.

### DETAILED DESCRIPTION

Example embodiments will now be described more fully with reference to the accompanying drawings. Embodiments, however, may be embodied in many different forms and should not be construed as being limited to the embodiments set forth herein. Rather, these example embodiments are provided so that this disclosure will be thorough and complete, and will fully convey the scope to those skilled in the art. In the drawings, the thicknesses of layers and regions are exaggerated for clarity.

It will be understood that when an element is referred to as being “on,” “connected to,” “electrically connected to,” or “coupled to” to another component, it may be directly on, connected to, electrically connected to, or coupled to the other component or intervening components may be present. In contrast, when a component is referred to as being “directly on,” “directly connected to,” “directly electrically connected to,” or “directly coupled to” another component, there are no intervening components present. As used herein, the term “and/or” includes any and all combinations of one or more of the associated listed items.

It will be understood that although the terms first, second, third, etc., may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. For example, a first element, component, region, layer, and/or section could be termed a second element, component, region, layer, and/or section without departing from the teachings of example embodiments.

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, and/or components.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Reference will now be made to example embodiments, which are illustrated in the accompanying drawings, wherein like reference numerals may refer to like components throughout.

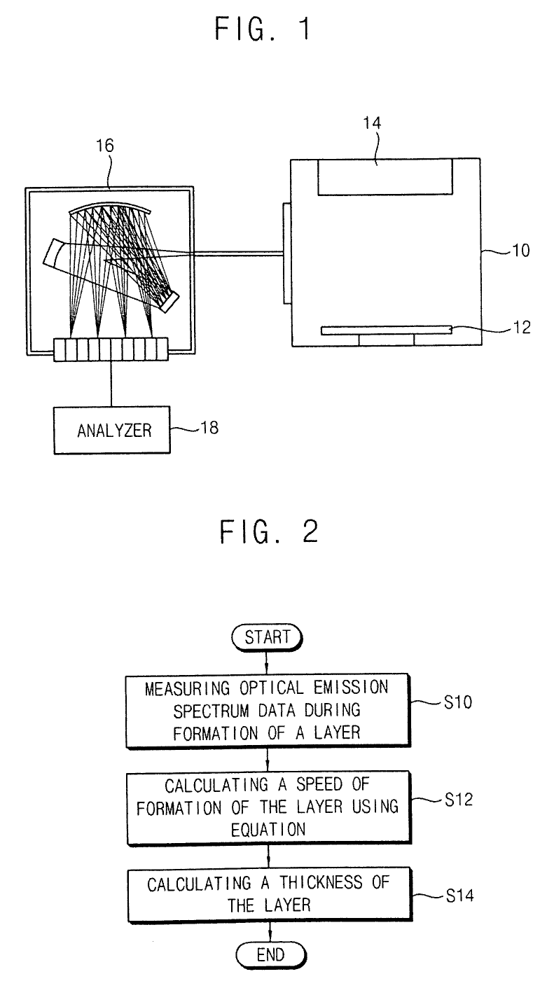

FIG. 1 is an apparatus for depositing of a layer on a substrate according to example embodiments. FIG. 2 is a flowchart illustrating a method of calculating a thickness of the layer according to example embodiments.

Referring to FIG. 1, a chamber 10 (e.g., a deposition chamber) may be provided. The chamber 10 may include a chemical vapor deposition (CVD) process chamber in which the layer may be deposited on a substrate using plasma. In example embodiments, the chamber 10 may be a plasma enhanced chemical vapor deposition (PECVD) process chamber.

The chamber 10 may include a chuck 12 for supporting the substrate, a gas supply member 14 for providing a source gas and/or a carrier gas, and/or a power source (not shown) for activating the source gas into a plasma state.

An optical emission spectroscopy (OES) 16 connected to the chamber 10 may be provided so that light particles emitted from the chamber 10 may be captured and/or spectrum data thereof may be produced. The OES 16 may be connected to an analyzer 18 for analyzing the spectrum data. That is, the analyzer 18 may calculate the thickness of the layer in real time based on the spectrum data and/or deposition conditions.

The analyzer 18 may be connected to a controller (not shown) that may change the deposition conditions applied to the chamber 10, and/or the deposition conditions may be input into the analyzer 18. Additionally, the thickness of the layer calculated by the analyzer 18 may be fed back to the controller. Based on the feedback data, the deposition conditions may be changed by the controller.

A method of calculating a thickness of a layer formed on a substrate in real time may be illustrated with reference to FIGS. 1 and 2.

Referring to FIGS. 1 and 2, the substrate may be loaded into the chamber 10. A source gas and/or an inert gas may be introduced into the chamber 10, and/or an electrical power may be applied to the chamber 10 so that the layer may be formed on the substrate. The deposition conditions such as pressure, temperature, gas flow rate, and/or power may be input into the analyzer 18. The inert gas may serve as a carrier gas.

When the layer is deposited on the substrate, radical generation reaction and/or layer deposition reaction may occur repeatedly. Generally, the radical generation reaction may progress relatively slowly, and thus may be a dominant factor for the speed of deposition of the layer. Alternatively, other factors may affect the speed of deposition according to types of the layers and/or specific deposition methods. In example embodiments, the speed of deposition may be calculated by the speed of radical generation reaction.

In step S10, when the layer is deposited on the substrate, optical emission spectrum data of plasma generated by the inert gas may be detected. The inert gas may include helium and/or argon. The optical emission spectrum data may be a basis for calculating the thickness of the layer in real time.

When the layer is deposited, excitation and relaxation of plasma may occur repeatedly, and/or the plasma may emit light. The wavelength and/or intensity of the light may be related to the progress of deposition, and/or the optical emission spectrum data may be detected so that the deposition progress may be checked out.

In example embodiments, the optical emission spectrum data may be detected by dividing the light emitted from the inert gas and/or measuring the intensity of each light divided according to wavelengths.

In the deposition process using the plasma, the optical emission spectrum data at the wavelength corresponding to the inert gas may be proportional to the speed of radical generation reaction, the excitation speed of the plasma, and/or the concentration of the plasma. Among the above, the speed of radical generation reaction may dominantly affect the speed of deposition of the layer, and thus may be used as basis data for calculating the deposition speed and/or thickness of the layer.

However, other factors may also dominantly affect the deposition speed according to the deposition conditions. For example, in some cases, the source gas may be the dominant factor of the deposition speed. Alternatively, in other cases, both the source gas and the inert gas may be the dominant factors of the deposition speed. Thus, in example embodiments, optical emission spectrum data of the source gas may be detected, and/or the thickness of the layer may be calculated using the same. In example embodiments, optical emission spectrum data of both the source gas and the inert gas may be detected, and/or the thickness of the layer may be calculated using the same.

In step S12, the deposition speed may be calculated using the optical emission spectrum data. The deposition speed may be calculated by applying the optical emission spectrum data to following Equation (1).

R_{layer}=k(p, T, . . . )Iᵢₙₜ (1)

Here, R_{layer} indicates the speed of deposition of the layer, k( ) indicates the function, p indicates the pressure, T indicates the temperature, and Iᵢₙₜ indicates the intensity of the optical emission spectrum data.

In step S14, Equation (1) may be integrated over time, so that the thickness of the layer may be calculated in real time from the intensity of the optical emission spectrum data Iᵢₙₜ. That is, Equation (1) may be converted into Equation (2) as follows.

Th_{layer}=k(p, T, . . . )∫₀^{t}Iintdt (2)

Here, Th_{layer} indicates the thickness of the layer deposited on the substrate.

Before calculating the deposition speed, Equation (1) may be obtained by several experiments, and/or Equation (1) may be used for calculating the thickness of the layer that is deposited on the substrate by the same recipe as that of the above experiments.

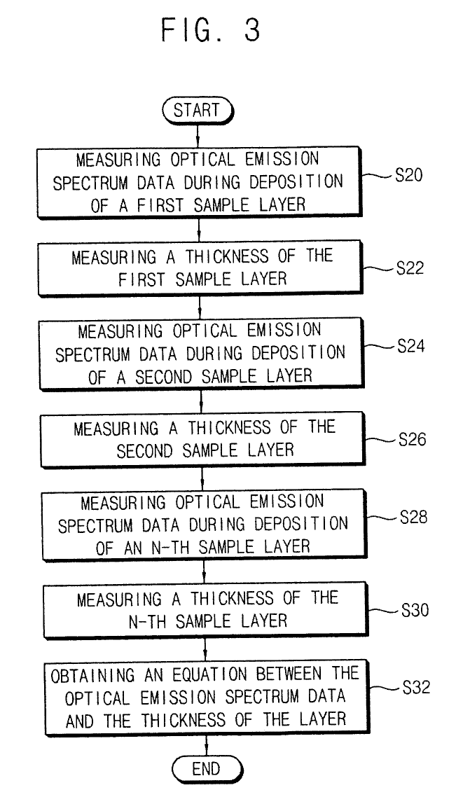

FIG. 3 is a flowchart illustrating a method of obtaining Equation (1) from the optical emission spectrum data.

In step S20, a first sample layer (not shown) may be deposited on a first substrate (not shown) in the chamber 10. When the first sample layer is deposited on the first substrate, the intensity of light emitted from the chamber 10 may be continuously measured to obtain a first optical emission spectrum data.

In step S22, the first substrate having the first sample layer may be unloaded from the chamber 10 and/or the thickness of the first sample layer may be measured.

In step S24, a second sample layer (not shown) may be deposited on a second substrate (not shown) in the chamber 10. The second sample layer may be deposited under the same conditions as those of the first sample layer. When the second sample layer is deposited on the second substrate, the intensity of light emitted from the chamber 10 may be continuously measured to obtain a second optical emission spectrum data.

In step S26, the second substrate having the second sample layer may be unloaded from the chamber 10 and/or the thickness of the second sample layer may be measured.

In steps S28 and S30, the above steps may be repeatedly performed so that an n-th sample layer (n is an integer larger than 2) may be deposited and/or the thickness thereof may be measured.

In step S32, Equation (1) may be deduced based on the optical emission spectrum data and/or the thicknesses of the sample layers deposited on the substrates at the same deposition conditions, such as an internal pressure of the chamber 10, a temperature of the chamber 10, a flow rate of the source gas, a power applied to the chamber 10, etc.

When a layer is deposited under the deposition conditions substantially the same as those of the above sample layers, Equation (1) may be used for calculating the thickness of the layer. That is, prior to measuring the thickness of the layer, Equation (1) may be obtained by depositing sample layers on substrates under the same conditions, and in the opposite direction, Equation (1) may be used for calculating the thickness of the layer.

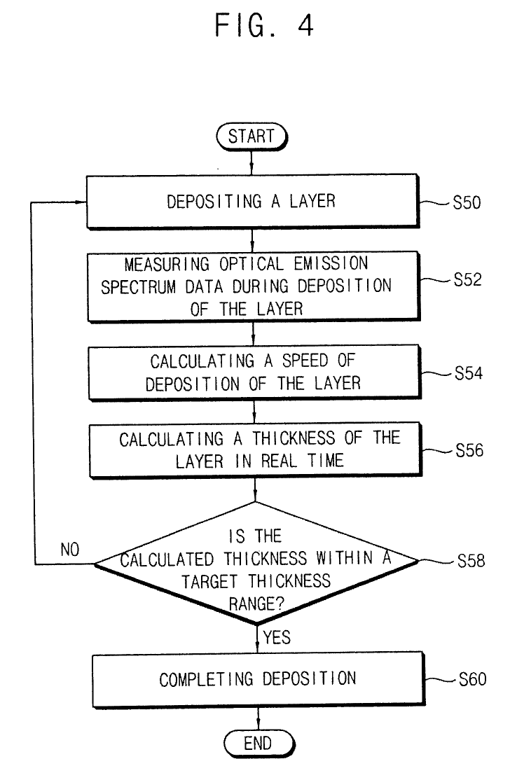

FIG. 4 is a flowchart illustrating a method of calculating a thickness of a layer formed on a substrate in real time.

In step S50, a layer (not shown) may be deposited on a substrate (not shown) loaded into a chamber (not shown). Particularly, a source gas and/or a carrier gas (e.g., an inert gas) may be introduced into the chamber, and/or a power for generating plasma may be applied to the chamber. Additionally, the pressure and/or temperature of the chamber may be controlled.

The thickness of the layer may be calculated in real time when the layer is deposited on the substrate. The method of calculating the thickness of the layer may be substantially the same as that illustrated with reference to FIGS. 1 and 2.

Particularly, in step S52, light emitted from the chamber during the deposition process may be divided according to wavelengths, and/or the intensity of the light at a specific wavelength may be detected so that optical emission data may be obtained. In step S54, the speed of deposition of the layer may be calculated using the optical emission spectrum. In step S56, the thickness of the layer deposited on the substrate may be calculated as follows.

Particularly, the obtained optical emission spectrum data may be put into Equation (1), including deposition conditions. Equation (1) may be integrated over time so that Equation (2) may be deduced. Thus, the thickness of the layer may be calculated from Equation (2).

In step S58, whether the thickness of the layer is or is not within a target thickness range may be decided. That is, when the thickness of the layer is under the target thickness range, the deposition process may be performed again. However, in step S60, when the thickness of the layer is within the target thickness range, the deposition process may end.

As illustrated above, the thickness of the layer deposited on the substrate may be calculated in real time and/or the layer having the target thickness may be formed.

When a thickness of a layer is measured using a measurement apparatus after the layer is deposited, only thicknesses of some layers may be measured because of time and/or cost. Thus, other layers that are not measured may not have the target thicknesses. However, in accordance with example embodiments, the thicknesses of all layers may be calculated, and/or all layers may have the target thicknesses. Additionally, extra time for measuring the thickness may not be needed because the thickness may be calculated in real time.

### Experiment on Relationship Between a Thickness of a Layer and Optical Emission Spectrum Data

### Experiment 1

A silicon oxide layer was deposited on a substrate using a source gas and a carrier gas in a PECVD process chamber. Silane gas was used as the source gas and helium gas was used as the carrier gas. During the deposition process, a peak value of optical emission spectrum data of the helium gas was measured. That is, a peak value of optical emission spectrum data at a wavelength of about 586.6 nm was measured.

After forming the silicon oxide layer, the thickness of the silicon oxide layer was measured by ellipsometry.

The above experiment was performed five times, that is, five sample silicon oxide layers (Samples 1 to 5) were deposited on five substrates, respectively.

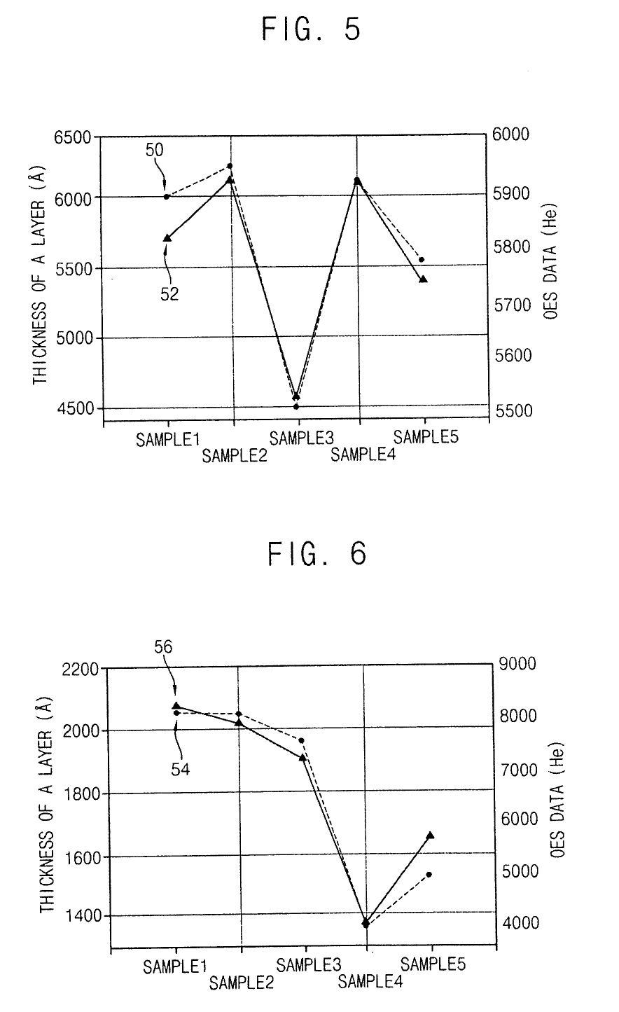

FIG. 5 is a graph showing the peak values of optical emission spectrum data of Sample 1 to 5 and the thicknesses of Sample 1 to 5 measured by ellipsometry. In FIG. 5, the peak values 50 of optical emission spectrum data of the helium gas are represented by , and the thicknesses 52 of the silicon oxide layers are represented by ▴. As shown in FIG. 5, the peak values 50 have some relationship with the thicknesses 52. Thus, a thickness of a layer may be calculated using the optical emission spectrum data in real time.

### Experiment 2

A silicon oxide layer was deposited on a substrate using a source gas and a carrier gas in a PECVD process chamber. Silane gas and oxygen gas were used as the source gas and helium gas and argon gas were used as the carrier gas. During the deposition process, a peak value of optical emission spectrum data of the helium gas was measured. The recipe of Experiment 2 was different from that of Experiment 1 in aspects of the source gas and the carrier gas.

After forming the silicon oxide layer, the thickness of the silicon oxide layer was measured by ellipsometry.

The above experiment was performed five times, that is, five sample silicon oxide layers (Samples 6 to 10) were deposited onto five substrates, respectively.

FIG. 6 is a graph showing the peak values of optical emission spectrum data of Sample 6 to 10 and the thicknesses of Sample 6 to 10 measured by ellipsometry. In FIG. 6, the peak values 54 of optical emission spectrum data of helium are represented by , and the thicknesses 56 of the silicon oxide layers are represented by ▴. As shown in FIG. 6, the peak values 54 have some relationship with the thicknesses 56. Thus, a thickness of a layer may be calculated using the optical emission spectrum data in real time.

### Experiment on Exactness of a Thickness of a Layer Calculated Using Optical Emission Spectrum Data

The thicknesses of Samples 6 to 10 were calculated by the above method using the optical emission spectrum data of the helium gas. Additionally, after forming Samples 6 to 10 on the substrates, the real thicknesses of Samples 6 to 10 were measured by ellipsometry.

Table 1 shows the thicknesses of Samples 6 to 10 that were calculated by the above method and measured by ellipsometry, respectively.

TABLE 1

| | | | Calculated | Real | Error |
|---|---|---|---|---|---|
| | | Peak | Thickness | Thickness | Rate |
| Sample | Intensity | Value | (Å) | (Å) | (%) |
| 6 | 8136 | 315022 | 2032 | 2071 | −1.87 |
| 7 | 8105 | 318796 | 2049 | 2022 | 1.35 |
| 8 | 7552 | 290477 | 1921 | 1909 | 0.63 |
| 9 | 3870 | 166235 | 1359 | 1370 | −0.81 |
| 10 | 4890 | 232139 | 1657 | 1647 | 0.65 |

In Table 1, Intensity means an intensity of optical emission spectrum data of helium, Peak Value means an integrated value of Intensity over time, and Error Rate means a percentage of the difference between Calculated Thickness and Real Thickness. As shown in Table 1, Error Rate is under ±2%, and thus a thickness of a layer deposited on a substrate may be calculated exactly in accordance with example embodiments.

According to example embodiments, a thickness of a layer may be calculated in real time during a deposition process, and thus the layer may be formed to have a target thickness.

While example embodiments have been particularly shown and described, it will be understood by those of ordinary skill in the art that various changes in form and details may be made therein without departing from the spirit and scope of the present invention as defined by the following claims.

What is claimed is:

1. A method of calculating a thickness of a layer, comprising:
forming the layer on a substrate in a chamber;
measuring optical emission spectrum data from the chamber; and
calculating the thickness of the layer from the optical emission spectrum data.

2. The method of claim 1, wherein calculating the thickness of the layer includes:
calculating a speed of formation of the layer from the optical emission spectrum data using an equation between the optical emission spectrum data and the speed of formation of the layer.

3. The method of claim 2, wherein calculating the thickness of the layer further includes:
integrating the equation over time.

4. The method of claim 2, wherein the equation includes the optical emission spectrum data multiplied by a function.

5. The method of claim 4, wherein obtaining the function includes:
depositing a sample layer on a substrate in the chamber;
detecting the optical emission spectrum data from the chamber during the depositing of the sample layer;
unloading the substrate having the sample layer from the chamber;
measuring a thickness of the sample layer; and
obtaining the function using a relationship between the optical emission spectrum data and the measured thickness of the sample layer.

6. The method of claim 2, wherein the equation includes the optical emission spectrum data multiplied by a function of one or more of an internal pressure of the chamber, a temperature of the chamber, a flow rate of source gas, and a power applied to the chamber.

7. The method of claim 6, wherein obtaining the function includes:
depositing a sample layer on a substrate in the chamber;
detecting the optical emission spectrum data from the chamber during the depositing of the sample layer;
unloading the substrate having the sample layer from the chamber;
measuring a thickness of the sample layer; and
obtaining the function using a relationship between the optical emission spectrum data and the measured thickness of the sample layer.

8. The method of claim 1, wherein forming the layer on the substrate includes performing a chemical vapor deposition (CVD) process using source gas and carrier gas.

9. The method of claim 8, wherein the source gas includes silane gas.

10. The method of claim 8, wherein the source gas includes oxygen gas.

11. The method of claim 8, wherein the carrier gas includes inert gas.

12. The method of claim 11, wherein the optical emission spectrum data is an intensity of light from the chamber at a wavelength of the inert gas.

13. The method of claim 11, wherein the inert gas includes helium gas.

14. The method of claim 11, wherein the inert gas includes argon gas.

15. The method of claim 1, wherein forming the layer on the substrate includes performing a plasma enhanced chemical vapor deposition (PECVD) process.

16. A method of forming a layer, comprising:
depositing the layer on a substrate in a chamber;
measuring optical emission spectrum data from the chamber;
calculating a thickness of the layer using the optical emission spectrum data; and
ending the depositing of the layer when the calculated thickness of the layer is within a target thickness range.

17. The method of claim 16, wherein calculating the thickness of the layer includes:
applying the optical emission spectrum data to an equation for calculating a speed of depositing the layer, wherein the equation includes the optical emission spectrum data and the depositing conditions; and
integrating the equation over time.

18. The method of claim 17, wherein the equation includes the optical emission spectrum data multiplied by a function of one or more of an internal pressure of the chamber, a temperature of the chamber, a flow rate of source gas, and a power applied to the chamber.

19. The method of claim 16, wherein depositing the layer on the substrate includes performing a chemical vapor deposition (CVD) process using source gas and carrier gas.

20. The method of claim 16, wherein depositing the layer on the substrate includes performing a plasma enhanced chemical vapor deposition (PECVD) process.
